(19) United States
(12) Patent Application Publication
(10) Pub. No.: US 2006/0068605 A1
(43) Pub. Date: Mar. 30, 2006

(54) Method of manufacturing oxide film and method of manufacturing semiconductor device

(75) Inventors: Hiroshi Katsumata, Sagamihara-shi (JP); Makoto Saito, Yokohama-shi (JP); Hiroshi Fujita, Yokohama-shi (JP); Eriko Nishimura, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Tokyo (JP)

(21) Appl. No.: 11/233,024

(22) Filed: Sep. 23, 2005

(30) Foreign Application Priority Data
Sep. 24, 2004 (JP) 2004-277911

(51) Int. Cl. H01L 21/31

(52) U.S. Cl. 438/788; 438/789

(57) ABSTRACT

A method of manufacturing an oxide film includes jetting onto a substrate a high-pressure solution containing an oxygen source and having a pressure of 5 MPa, and forming an oxide film on the substrate using the jetted high-pressure solution.

### CROSS REFERENCE TO RELATED APPLICATIONS

This application is based upon and claims the benefit of priority from prior Japanese Patent Application No. 2004-277,911 filed on Sep. 24, 2004; the entire contents of which is incorporated by reference herein.

### BACKGROUND OF THE INVENTION

1. Field of the Invention

This invention relates to a method of manufacturing an oxide film and a method of manufacturing a semiconductor device, and more particularly relates to a method of manufacturing an oxide film on a substrate, and a semiconductor device manufacturing method which is applied to manufacturing a high quality oxide film at a low temperature.

2. Description of the Related Art

Oxide films have been widely applied to a variety of semiconductor devices, and should be relatively free from defects and have excellent interface states when used as gate oxide films for MOS (Metal Oxide Semiconductor) transistors.

Generally speaking, thermal oxide films have been used as gate oxide films of Si semiconductor devices. Such thermal oxide films have to be heat-treated at a temperature of 800° C. or higher. However, with a TFT (thin film transistor) device used for a liquid crystal display and so on, a Poly-Si device should be prepared on a glass substrate. In such a case, the thermal oxide films should be treated at approximately 400° C. or lower which is an allowable temperature limit of glass. Therefore, TEOS (Tetraethyl orthosilicate) films which can be deposited by CVD (Chemical Vapor Deposition) at 400° C. or lower are usually applied as gate oxide films for TFT devices.

Recently, soft organic films are being used in place of TFT glass substrates. Electric paper, a sheet computer or a wearable computers is prepared on an organic film. Such a device also requires MOSFET (MOS Filed Effect Transistor) elements which have an excellent operation rate and low power consumption. Therefore, oxide films or gate oxide films are essential factors as well as organic and non-organic semiconductor layers. Since organic films have a heat resistance of 100° C. to 200° C. or lower, there is a demand for a method of depositing a gate oxide film at low temperature without damaging a semiconductor layer of the organic film.

The following methods have been mainly studied at present, i.e., the plasma oxidation (refer to non-patent publications: S. Uchikoga et al. “Appl. Phys. Lett., 75(1999), p 725, and Y. Kawai et al. “Appl. Phys. Lett., 64(1994), p. 2223), and low energy ion beam oxidation (non-patent publication: W. Shindo, and T. Ohmi “J. Appl. Phys., 79(1996), P. 2347).

In both of them, oxygen atoms and molecules are ionized, and are given kinetic energy by applying a voltage. Oxygen ions or neutral radicals are physically radiated onto an Si substrate in order to oxide a surface thereof. Further, chemical oxidization is also studied using O₃ water or ultra-violet beams, thereby a surface layer of the substrate is oxidized only through the chemical reaction.

The plasma oxidization and ion beam oxidization enable deposition of oxide films at a low temperature. However, it is difficult to deposit high quality oxide films since the oxide film and substrate are easily damaged by charged particles (ions, electrons, etc.) or electromagnetic waves (UV rays, x-rays, etc.). Oxide films prepared by the foregoing methods at a room temperature have a low breakdown voltage, and a high leakage current and a high flat band voltage (V_{FB}). Therefore, it is necessary to raise a substrate temperature to approximately 400° C. in order that the quality of the foregoing oxide films is improved to be equal to the quality of a thermal oxide film.

The chemical oxidization is relatively effective in preventing damages on oxide films and substrates. However, since the surface of the thin substrate which is approximately 4 nm to 5 nm thick is oxidized only through the chemical reaction, the quality of the oxide film is adversely affected. Therefore, it is very difficult to obtain a gate oxide film which is 10 nm or thicker and is applicable to a semiconductor device demanded at present.

### BRIEF SUMMARY OF THE INVENTION

The present invention is intended to provide not only a method of manufacturing at a low temperature an oxide film which is relatively free from damages and is applicable to a semiconductor device, but also a semiconductor device manufacturing method including the oxide film manufacturing method.

According to a first aspect of the embodiment of the invention, there is provided a method of manufacturing an oxide film, including jetting onto a substrate a high-pressure solution containing an oxygen source and having a pressure of 5 MPa, and forming an oxide film on the substrate using the jetted high-pressure solution.

In accordance with a second aspect of the embodiment of the invention, there is provide a method of manufacturing an oxide film, including: lowering a resistance of a solution serving as an oxygen source; heating the solution to a room temperature or higher; applying a pressure of 5 MPa or higher to the solution; jetting the pressurized solution onto a substrate; and depositing an oxide film using the jetted high-pressure solution.

According to a third aspect of the embodiment of the invention, there is provided a method of manufacturing a semiconductor device, including: jetting onto a substrate a high-pressure solution which contains an oxygen source and has a pressure of 5 MPa or higher; depositing an oxide film on the substrate using the high-pressure solution; and forming an electrode on the oxide film, and forming an element having the oxide film and the electrode.

### BRIEF DESCRIPTION OF THE SEVERAL VIEWS OF THE DRAWINGS

FIG. 1 shows the configuration of a substrate treating unit according to an embodiment of the invention;

FIG. 2 is a perspective view of a part of the substrate treating unit, showing the relationship between a substrate and a nozzle;

FIG. 3 is a schematic view showing the positional relationship between a silicon wafer and the nozzle which are used in examples 1 and 2 of the embodiment of the invention;

FIG. 4 is a graph showing the relationship between thickness of oxide films (optical film thickness) and a period of time for jetting high pressure deionized water, the oxide films being produced using an oxide film depositing method in first and second examples;

FIG. 5A is a graph showing an XPS spectrum of a silicon wafer;

FIG. 5B is a graph showing XPS spectra of 2.7 nm-thick thermal oxide films on the silicon wafer;

FIG. 6 shows a structure model constituted by an oxide film and a damaged layer which are used to calculate optical film thickness;

FIG. 7 is a graph showing the relationship between thickness (Tox) of oxide films, and thickness (Td) of damaged layers;

FIG. 8A is a graph showing results of 100 kHz C-V measurement of MHz-cleaned oxide films;

FIG. 8B a graph showing results of 100 kHz C-V measurement of oxide films (made by jetting 26° C. high-pressure water in the first example,);

FIG. 8C is a graph showing results of 100 kHz C-V measurement of a MOS-structure using oxide films (made by jetting 48° C. high-pressure water in the second example);

FIG. 9A is a graph showing results of QS (Quasi static)-CV measurement of the MOS structure of a thermal oxide film;

FIG. 9B is a graph showing results of QS (Quasi static)-CV measurement of the MOS structure of an MHz-cleaned thermal oxide film;

FIG. 9C is a graph showing results of QS (Quasi static)-CV measurement of the MOS structure of the thermal oxide film in the first embodiment (using 26° C. high-pressure water);

FIG. 9D is a graph showing results of QS (Quasi static)-CV measurement of the MOS structure of the thermal oxide film in the second embodiment (using 48° C. high-pressure water);

FIG. 10 is a graph showing results of 100 kHz and QS (Quasi static) CV measurements and of the MOS structure including a plasma oxide film (formed at 400° C.);

FIG. 11 is a graph showing IV characteristics of the MOS structure including the oxide film of the second embodiment; and

FIG. 12 shows the configuration of a substrate treating unit in further embodiments of the invention.

### DETAILED DESCRIPTION OF THE INVENTION

The present invention will be described with reference to an embodiment shown in the drawings.

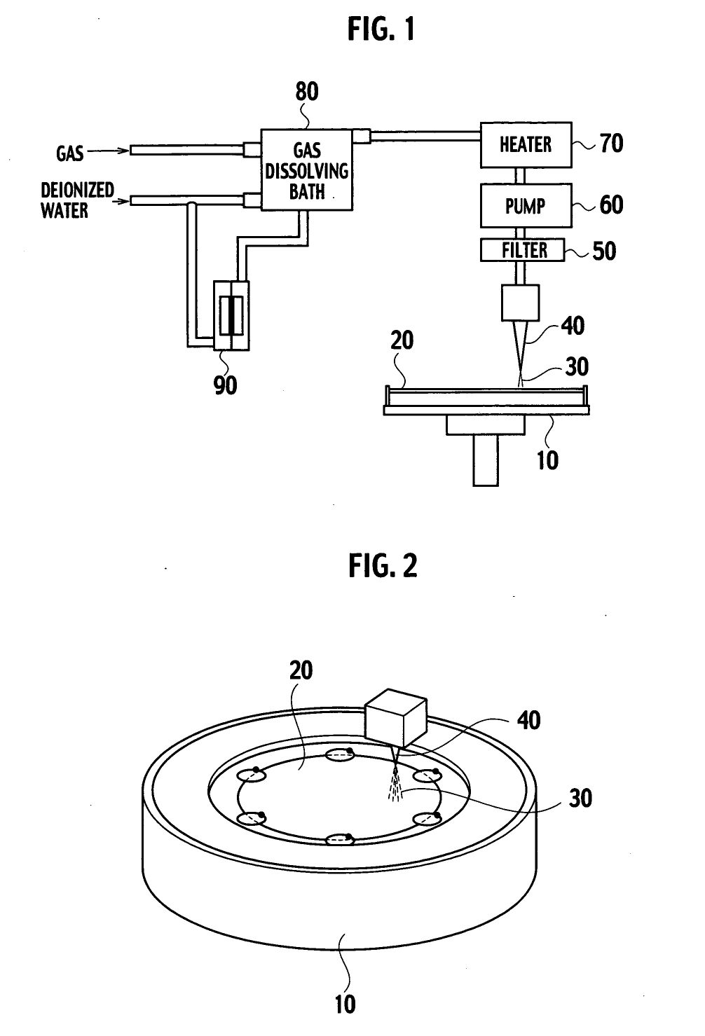

Referring to FIG. 1, a substrate treating unit jets a high pressure solution onto a surface of a substrate such as a silicon wafer 20 or the like. The substrate is fixedly placed on a substrate stand 10.

The substrate treating unit comprises a feeder which supplies a solution containing an oxygen source to the surface of the substrate, a unit pressuring the solution, and a nozzle jetting the pressurized solution onto the surface of the substrate.

Specifically, the solution containing the oxygen source may be water or a variety of aqueous solutions. Water molecules themselves may be used the oxygen source. Further, ozone or oxygen containing gases such as carbon dioxide may be used as the oxygen source, and be dissolved in the aqueous solution. The aqueous solution may be a soluble detergent, alcohol, and so on.

Deionized water is preferable in order to prevent impurities. However, the deionized water usually has a very high specific resistance of MΩ or larger. If such deionized water is simply jetted onto the substrate, the substrate will be charged to 1000 V or more, which will set off adsorption of particles onto the substrate, and damage elements, and so on (i.e., breaking of an insulating film, etc.). In order to overcome this problem, the specific resistance of the deionized water should be controlled by introducing a minute amount of a CO₂ gas or the like.

FIG. 1 shows the substrate treating unit which uses the deionized water as a high pressure solution. The deionized water produced by a water purifying apparatus such as an ion exchanger is mixed with the CO₂ gas or the like in an gas dissolving bath 80. In this process, the specific resistance of the deionized water is lowered to a level where the substrate is not charged. Specifically, at a temperature of 25° C., the deionized water has preferably the specific resistance of 0.1 MΩcm to 1 MΩcm and pH 4 to pH 6. Further, the CO₂ gas in the amount of 1 mg/l to 100 mg/l may be added to the deionized water whose specific resistance is 18 Ωcm.

Any gases which can lower the specific resistance of the deionized water can be used in place of the CO₂ gas. Gases containing the CO₂ gas or the like as the oxygen source are effective in preventing charging of the substrate surface.

Referring to FIG. 1, a bypass is provided between the deionized water source and the gas dissolving bath 80, and an electrolytic bath 90 is provided in the bypass in order to monitor the specific resistance of the deionized water.

The aqueous solution containing the CO₂ gas is heated by a heater 70 if necessary, is pressurized by a pump 60, passes through a filter 50, and is substantially vertically jetted via a high-pressure water nozzle 40 (called the “nozzle 40”) onto a surface of a silicon wafer 20 placed on the substrate stand 10.

FIG. 2 schematically shows the relationship between the silicon wafer 20 on the substrate stand 10 and the nozzle 40. In this case, a spinner is used as the substrate stand 10. The nozzle 40 is movable along the periphery of the silicon wafer 20 in order to deposit an oxide film selectively or entirely on the silicon wafer 20. The substrate stand 10 may be structured to move the silicon wafer 20 two-dimensionally while the nozzle 40 may be fixedly attached. Further, the substrate stand 10 may be stationary while the nozzle 40 may be two-dimensionally movable.

It is preferable for the pump 60 to apply a pressure of 5 MPa or higher to the solution at an outlet of the nozzle 40. If the pressure is below 5 MPa, it is difficult to attain an effective deposition rate of the oxide film. From a practical standpoint, the pressure should be 10 MPa or higher, or preferably 20 MPa or higher. However, the pressure of 50 MPa or higher is not preferable since the pump 60 or the nozzle 40 may be subject to a heavy burden.

Referring to FIG. 2, the high-pressure water is vertically jetted onto the silicon wafer 20. Alternatively, the high-pressure water may be divergently jetted via the nozzle 40. For instance, the high-pressure water may diverge by approximately 15° with respect to the vertical from the nozzle 40. However, if the high-pressure water is divergent by more than 30°, the advantage of the high-pressure water is extensively affected depending upon a distance between the nozzle 40 and the silicon wafer 10, so that it is very difficult to control a jetting rate of the high-pressure water.

The high-pressure water can be jetted in the atmosphere. The substrate stand 10 is preferably provided with a splash preventing cover or a recovery sink for the high-pressured water. Neither vacuum equipment nor sealed chamber is necessary. However, if alcohol or the like whose flash point is low is dissolved in the aqueous solution, an anti-blast unit should be provided.

The oxide film will be deposited on the silicon wafer 20 by the substrate treating unit as will be described hereinafter.

Any kinds of substrates may be used so long as they are provided with metal layers or semiconductor layers onto which the oxide film can be deposited.

First of all, the substrate has its surface cleaned using the deionized water, and is fixedly placed on the substrate stand 10 as shown in FIG. 2. Further, the substrate may be cleaned on the substrate stand 10 as will be described later.

Positions of the nozzle 40 and the substrate are adjusted, so that a position where the oxide film should be deposited is determined. Then, the high-pressure water is substantially vertically jetted onto the silicon wafer 20.

The pressure of the high-pressure water at a nozzle outlet is approximately 5 MPa or higher, preferably 10 MPa to 50 MPa, and more preferably 20 MPa to 30 MPa.

A temperature of the high-pressure water is adjusted by the heater 70. The high-pressure water is adjustable between a room temperature and 100° C., but is preferably 40° C. or higher in order to improve the film depositing rate and the quality of the oxide film. However, the high-pressure water is preferably 60° C. or lower in order to prevent evaporation thereof.

The high-pressure water is jetted while the silicon wafer 20 is rotated or is two-dimensionally moved. In this state, the nozzle 40 is relatively moved on the silicon wafer 20 at the relative moving rate of 1 mm/sec to 10 mm/sec, and preferably 5 mm/sec.

An oxide film is deposited on the silicon wafer 20. The oxide film has a very low interface rate and a good quality compared with an oxide film which is deposited by the plasma CVD method using charged particles.

Thickness of the oxide film is adjustable depending upon the pressure and temperature of the high-pressure water, relative speed of the nozzle 40, and period of time of jetting the high-pressure water. The oxide film is 5 nm or more thick, and is applicable to a variety of semiconductor devices.

When a conductive film is formed on the foregoing oxide film, MOS will be accomplished. The oxide film manufacturing method is applicable to diodes or transistors of a variety of semiconductor devices. Further, the oxide film is applicable to a gate oxide film of a MOS transistor. Such a MOS transistor has low power consumption because of a low threshold voltage and a low leakage current. Since the oxide film can be deposited at a low temperature, the foregoing method is effective in depositing oxide films not only on silicon substrates but also on glass substrates and on resin sheets.

### EXAMPLES

The oxide films have been manufactured by the method of the present invention, and are compared with oxide films manufactured by a method of the related art. Their qualities have been evaluated.

### Example 1

For convenience of the evaluation, an approximately 2.7 nm thick thermal oxide film is deposited on an n-type silicon wafer by thermal treatment at 900° C. The Si substrate has a specific resistance of 1 Ωcm to 2 Ωcm. The substrate is cleaned for approximately 20 minutes using an ultrasonic washing machine (MHz).

The oxide film is deposited on the thermal oxide film of the silicon wafer. High-pressure water 30 is prepared by dissolving CO₂ gas of 5 mg/l in deionized water having the specific resistance of 18 MΩ cm. The high-pressure water 30 has the specific resistance of 0.5 Ωcm and pH 5.3, and is 26° C.

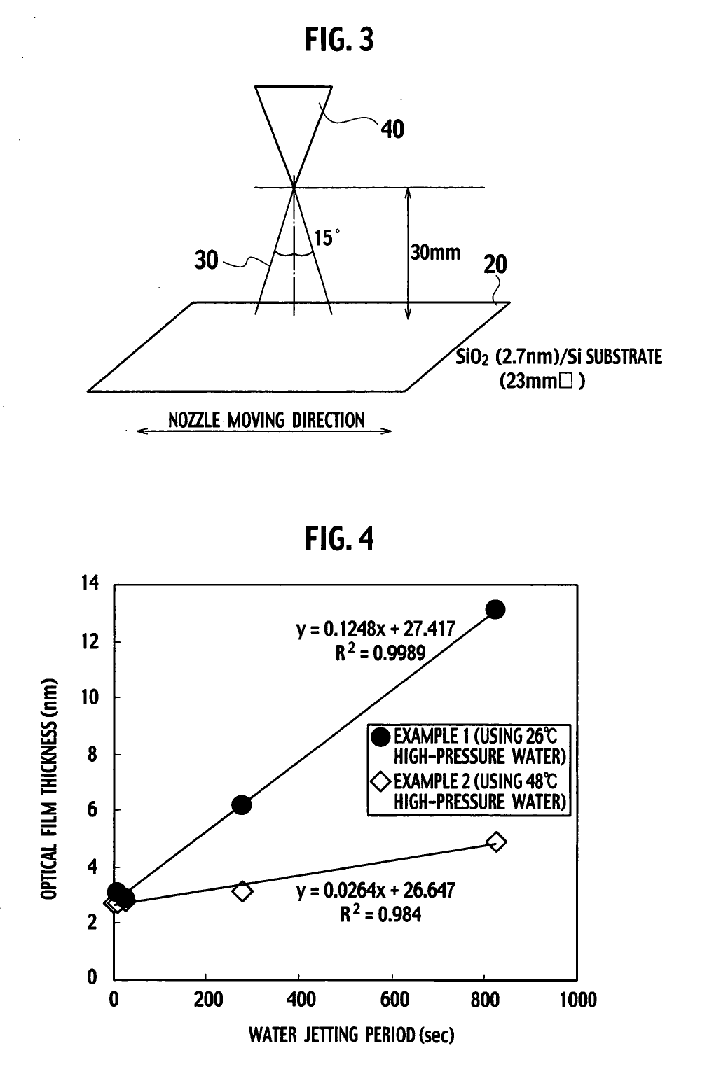

As shown in FIG. 3, the high-pressure water 30 is substantially vertically jetted onto the silicon wafer 20 via the nozzle 40. The pressure of the high-pressure water 30 at the outlet of the nozzle 40 is 20 MPa, and a distance between the nozzle 40 and the silicon wafer 20 is 30 mm. The high-pressure water 30 diverges approximately 15 degrees via the nozzle 40.

The nozzle 40 moves at a relative speed of 5 mm/sec. The high-pressure water is jetted for 9 seconds to 828 seconds when a cumulative time period in which the nozzle 40 passes over the substrate is calculated in terms of a high-pressure water jetting period.

### Example 2

In Example 2, the high-pressure water 30 is set to be 48° C. The remaining conditions are the same as those in Example 2.

<Evaluation>

FIG. 4 shows the relationship between the high-pressure water jetting period and the optical film thickness of the oxide films in Examples 1 and 2.

The optical film thickness is derived by measuring a single layer model of SiO₂(n=1.46)/Si(n=3.86) using an optical coating thickness gauge. When the high-pressure water temperatures are respectively 26° C. and 48° C. in Examples 1 and 2, the thickness of the oxide films are confirmed to increase in proportion to the jetting period. In other words, jetting of the high-pressure water is effective in manufacturing the oxide film with excellent controllability. The hotter the high-pressure water, the higher the oxidizing rate. When the high-pressure water is 48° C., the oxidizing rate is assumed to be approximately 0.75 nm/min.

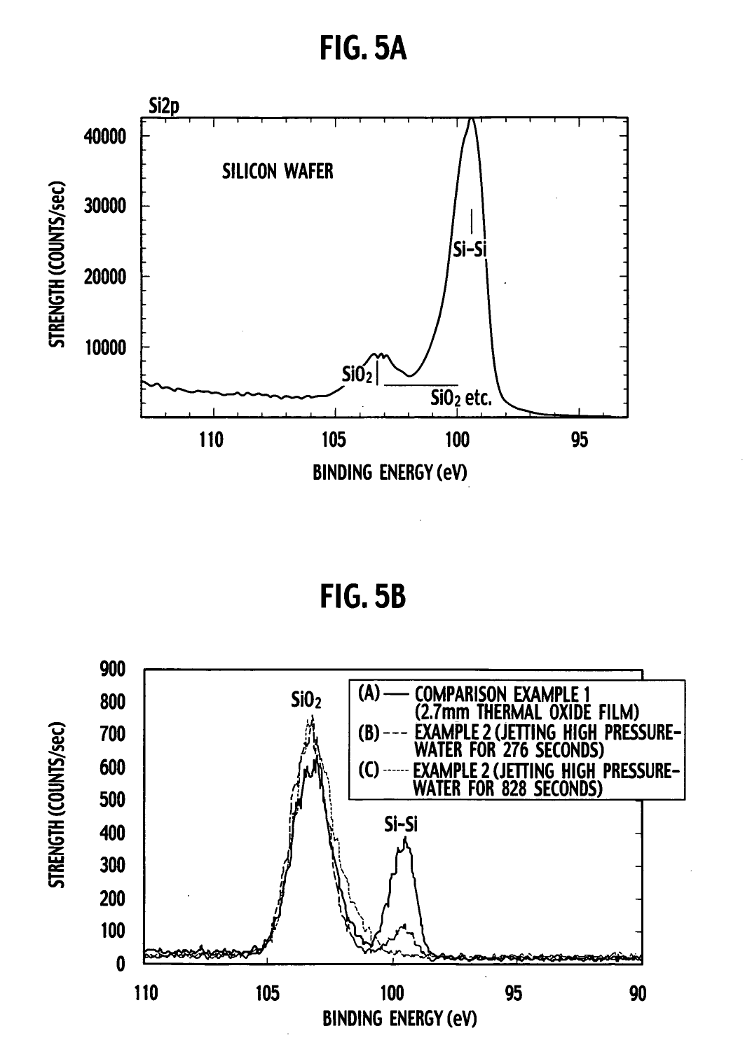

FIGS. 5A and 5B shows results of XPS (x-ray photoelectron spectrometry) conducted in order to confirm compositions of the oxide films made according to the invention. FIG. 5A shows the result of XPS of a silicon wafer (bare Si) to which no thermal oxidation is conducted, the result being shown as a reference. As shown in FIG. 5A, a narrow peak representing Si—Si bonding is present near 99 eV, which implies the presence of an Si layer. Further, an SiO₂ peak is slightly present near 103 eV, which is caused by native oxide.

In FIG. 5B, (A) denotes a comparison Example 1 (in which a 2.7 nm thick thermal oxide film is deposited on a silicon wafer), (B) denotes an oxide film of Example 2 (which is deposited by jetting 48° C. high-pressure water onto the silicon wafer for 276 seconds), and (C) denotes an oxide film of Example 2 (which is deposited by jetting 48° C. high-pressure water onto the silicon wafer for 828 seconds).

With the oxide films shown by (B) and (C), peaks of binding energies of SiO₂ are larger than a binding energy of Si—Si bonding. This means that the oxide films are reliably grown.

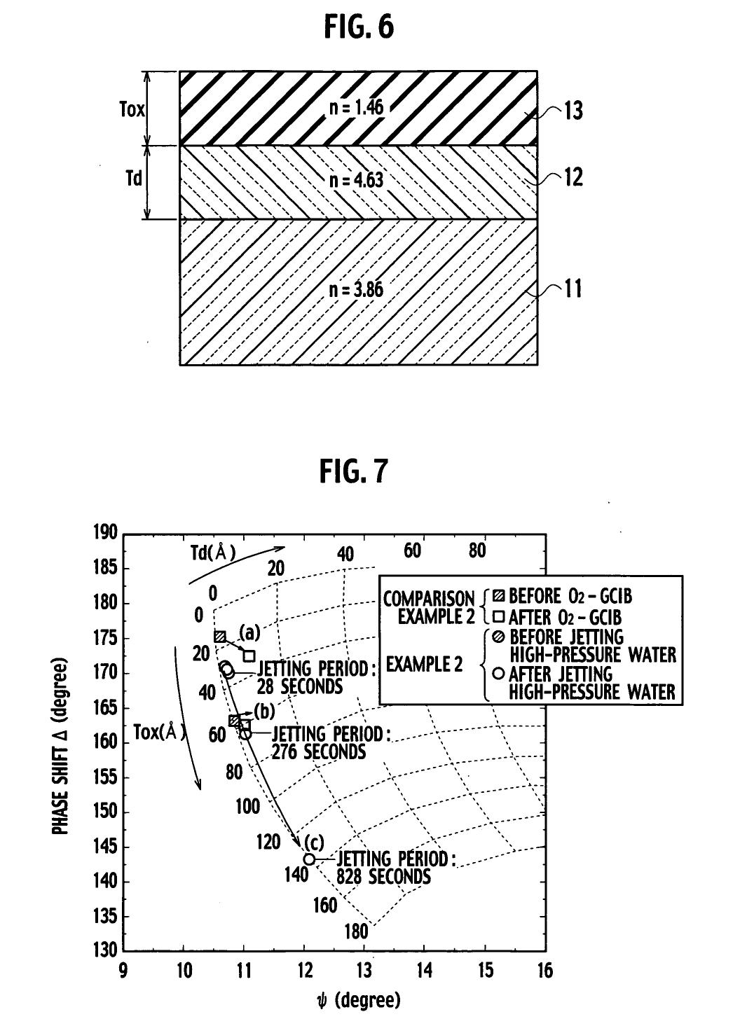

In order to observe how the silicon wafer is damaged by the oxidation method of the embodiment, the relationship between SiO₂ thickness (Tox) and thickness of a damaged Si layer (Td) are measured by the optical ellipsometry. Refer to FIG. 7. For this observation, it is assumed that a damaged layer 12 is sandwiched between an Si substrate layer 11 and an SiO₂ layer 13 as shown in FIG. 6. Further, it is assumed that a refractive index “n” of the Si layer 11 is 3.86, that of the damaged layer is 4.63, and that of the SiO₂ layer 13 is 1.46. In FIG. 7, the ordinate denotes a phase shift Δ of the “s” and “p” waves irradiated onto the substrates, and the abscissa denotes angles (Ψ) of intensity ratio of reflected light.

FIG. 7 also shows a comparison Example 2 in which an oxide film is produced by the Gas Cluster Ion Beam method (O₂-GCIB), which is known as one of the existing oxide film depositing methods which are relatively free from damages. Further, FIG. 7 shows thickness of the SiO₂ film and thickness of the damaged Si layer deposited under Vacc=5.3 keV at the room temperature and dose=1×10¹⁴ cm⁻² are also shown in FIG. 7.

In the oxidation method using O₂-GCIB, clusters made of approximately 2000 oxygen atoms are irradiated. Even when acceleration energy is somewhat high, energy per oxygen atom is small, so that it is possible to suppress damages caused on the substrate. For instance, if oxygen clusters are irradiated onto the substrate at the acceleration energy of 5.3 keV, the energy per oxygen atom (ion) is 2 eV to 3 eV at most. Therefore, the oxide film can be made by reducing damages. However, a damaged layer is caused to a certain degree.

With the method using O₂-GCIB, the oxygen gas cluster ion beams are irradiated onto the Si substrate over which an approximately 1.8 nm thick native oxide extends, thereby making an approximately 3 nm thick SiO₂ oxide film. In such a case, an approximately 1 nm thick damaged layer is also formed (as shown at (a) in FIG. 7). Further, when an approximately 5.8 nm thick thermal oxide film is formed in order to obtain a 6 nm thick SiO₂ oxide film, several-ten-nm thick damaged layer is also caused (refer to (b) in FIG. 7)

In Example 2, no damaged layer is caused when high-pressure water is jetted onto the Si substrate on which an approximately 3 nm thick thermal oxide film is formed, thereby obtaining an approximately 13 nm thick SiO₂ oxide film. In this case, no damaged layer is caused. It is confirmed that the oxide film depositing method of the invention can produce oxide films without any damaged layers.

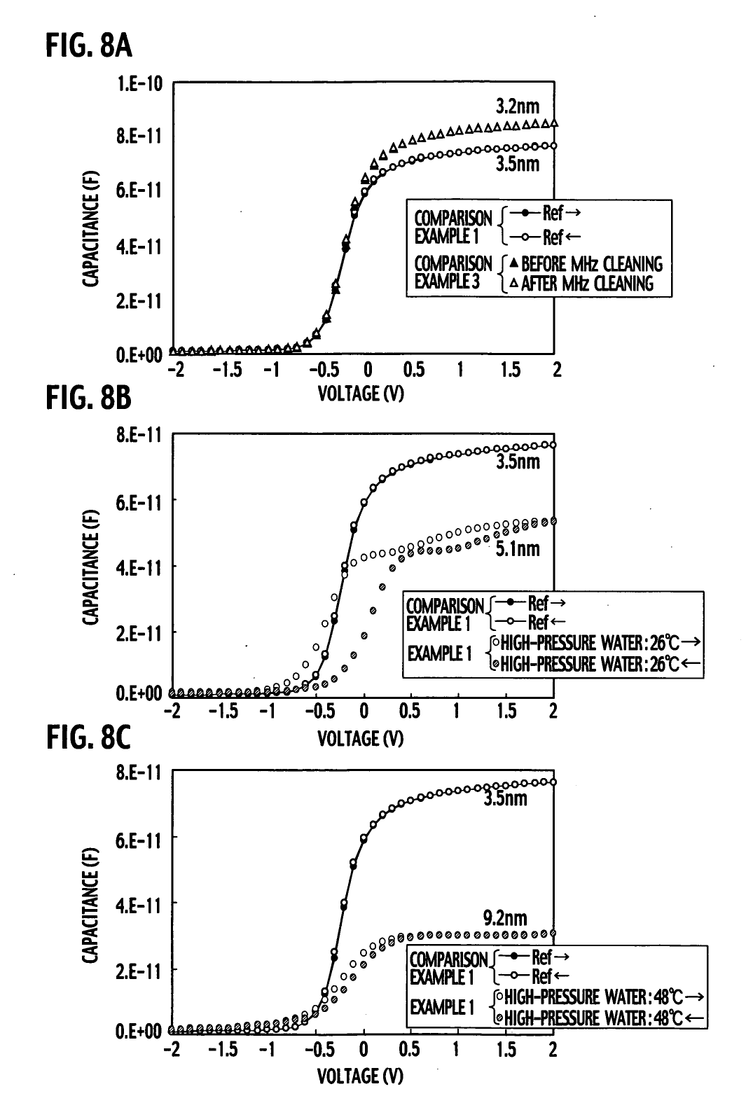

The C-V measurement is conducted for oxide films of Examples 1 and 2, those of the comparison examples, and silicon substrate layers in order to observe their interface states (SiO₂/Si interfaces). Refer to FIGS. 8A to 8C. For this measurement, Al electrodes of φ100 μm and having 400 nm thickness are deposited on the oxide films by the evaporation method. In FIGS. 8A to 8C, arrows denote voltage sweeping directions.

Results of C-V measurement of two comparison examples in which only thermal oxide films are deposited on Si substrates are shown in FIG. 8A. In Comparison Example 1, no treatment is applied to the oxide film (shown by ┌Ref┘). In Comparison Example 3, the thermal oxide film is subject to the MHz ultrasonic cleaning (shown by ┌after MHz cleaning┘. In FIGS. 8A, 8B and 8C, numerals denote thickness of the thermal oxide films obtained by the C-V measurement. The thickness is derived by assuming that a specific inductive capacity of SiO₂ is 3.9 on the basis of 100 kHz HF-CV measurement. The curves shown in FIG. 8A denotes qualities of the good thermal oxide films which are substantially free from damaged layers and hysteresis. The C-V curves are not affected by the MHz cleaning, which means that no damaged layer is caused by the MHz cleaning.

FIG. 8B shows C-V measurement results of oxide films which are produced by jetting 26° C. high-pressure water. FIG. 8C shows C-V measurement results of oxide films which are produced by jetting 48° C. high-pressure water.

Further, FIGS. 8B and 8C show the C-V measurement results of the 3.5 nm thick and MHz-cleaned thermal oxide film of the Comparison Example 1. Some hysteresis is observed in the C-V curve of the oxide film which is made by jetting 26° C. high-pressure water in the Example 1, while no hysteresis is observed in the C-V curve of the oxide film which is made by jetting 48° C. high-pressure water in the Embodiment 2. The oxide film of the Example 2 is confirmed to have an excellent interfacial quality.

The thickness values (of the C-V measurement) shown in FIGS. 8A to 8C somewhat differ from those measured by the ellipsometry as shown in Table 1. The following reasons are conceivable. The thickness of oxide films is calculated using the formula C=εS/d (where C denotes a storage capacitor,; d denotes thickness; S denotes an area of electrode; and ε denotes a dielectric constant). The storage capacitor C depends upon frequencies. The lower the frequencies, the larger the storage capacitor C. A relatively low C frequency of 100 kHz is used for the C-V measurement. Therefore, the thickness of C-V measured oxide films seems to be larger than the thickness obtained the ellipsometry.

TABLE 1

| | Thickness (nm) | |
|---|---|---|
| | (by C-V | Optical thickness |
| | measurement) | (by ellipsometry) |
| Thermal oxide film | 3.5 | 2.7 |
| (Comparison Example 1) | | |
| MHz-cleaned thermal oxide film | 3.2 | 2.7 |
| (Comparison Example 2) | | |
| Oxide film formed using 26° C. | 5.1 | 4.9 |
| high-pressure water | | |
| (Example 1) | | |
| Oxide film formed using 48° C. | 9.2 | 13.1 |
| high-pressure water | | |
| (Example 2) | | |

Table 2 shows flat band voltages (V_{FB}) and hysteresis width (ΔV_{FB}) which are derived on the basis of Table 1. It has been confirmed based on FIGS. 8A to 8C. It has been confirmed that the MHz-cleaned oxide films have the characteristics which are substantially similar to those of the oxide film to which no treatment has been done. Further, the oxide films are not affected by oxidation and are free from damages.

The thicker the oxide films, the larger the flat band voltage (V_{FB}). This is because a quantity of fixed charge in the oxide film seems to be proportional to the thickness of the oxide film. The flat band voltage (V_{FB}) is largest in the Example 2 in which 48° C. high pressure water is jetted. On the other hand, the hysteresis width (ΔV_{FB}) is approximately 0.1 V even after 48° C. high pressure water is jetted. This is because even when the oxide film becomes thicker, the quality of SiO₂ film remains uniform in the depth direction, and an Si/SiO₂ interface is relatively good.

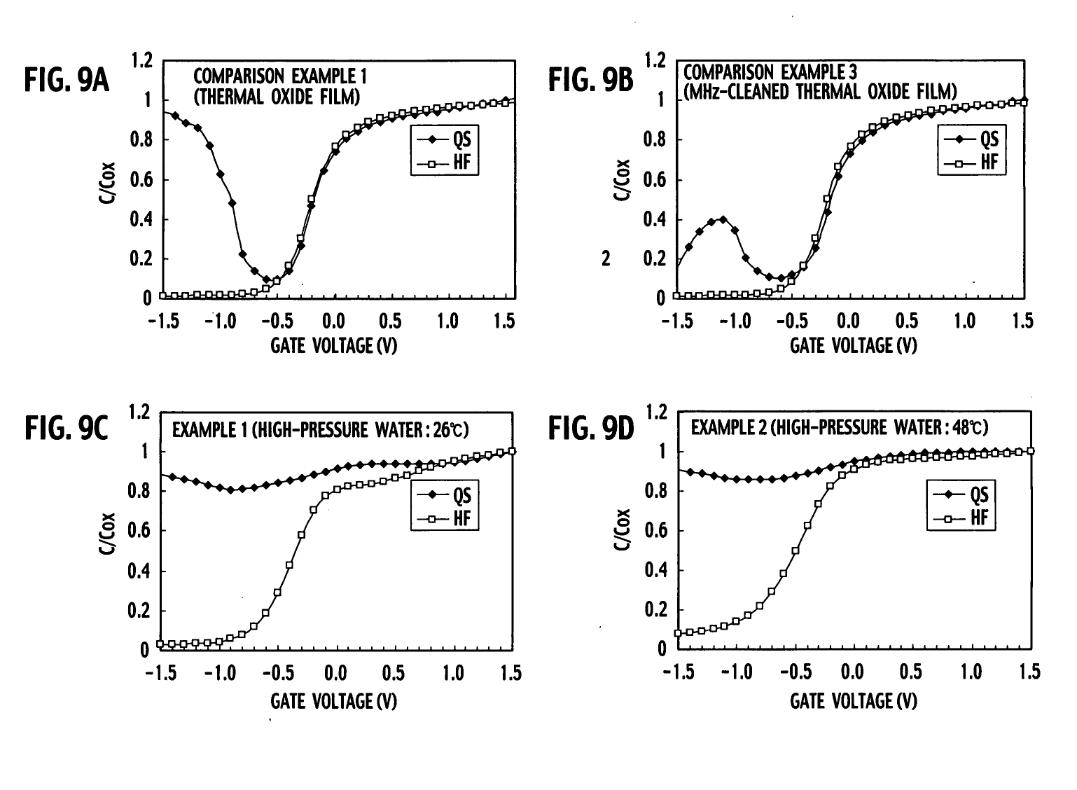

FIGS. 9A to 9D are graphs showing QS (Quasi Static)-CV characteristics of the oxide films. In these drawing figures, QS denotes quasi static-CV characteristics while HF denotes HF-CV characteristics shown in FIGS. 8A to 8C.

Table 2 also shows Dit (minimum interface state density SiO₂/Si interface) calculated on the basis of the QS and HF-CV shown in FIGS. 9A to 9D in addition to the flat band voltage (V_{FB}) and hysteresis width (ΔV_{FB}).

TABLE 2

| | | | | Dit (eV⁻¹ · |
|---|---|---|---|---|
| | V_{FB} (V) | C/Cmax | Δ V_{FB}(V) | cm⁻²) |
| Thermal oxide film | −0.38 | 0.20 | 0.0 | 1.1E+11 |
| (Comparison Example 1) | | | | |
| MHz-cleaned thermal | −0.38 | 0.20 | 0.0 | 9.8E+10 |
| oxide film | | | | |
| (Comparison Example 3) | | | | |
| Oxide film made using | −0.52 | 0.25 | 0.4 | 1.2E+13 |
| 26° C. high- | | | | |
| pressure water | | | | |
| (Example 1) | | | | |
| Oxide film made using | −0.70 | 0.30 | 0.1 | 1.4E+13 |
| 48° C. high- | | | | |
| pressure water | | | | |
| (Example 2) | | | | |

The thermal oxide film (Comparison Example 1) and the MHz-cleaned thermal oxide film (Comparison Example 3) have a Dit value of approximately 1×10¹¹ eV⁻¹ cm⁻². On the other hand, the oxide films of the Examples 1 and 2 has a Dit value of 1×10¹³ eV⁻¹ cm⁻². This is because high-pressure water is jetted onto the substrates, so that H₂O and CO₂ particles in the high-pressure water have certain kinetic energies, and knock-on the oxide films on the substrates. Split up oxygen atoms reach the Si substrate, thereby finally oxidizing Si.

A Dit value of a TEOS film formed at 350° C. substrate is 1×10¹² eV⁻² cm⁻², and V_{FB} is approximately −1 V.

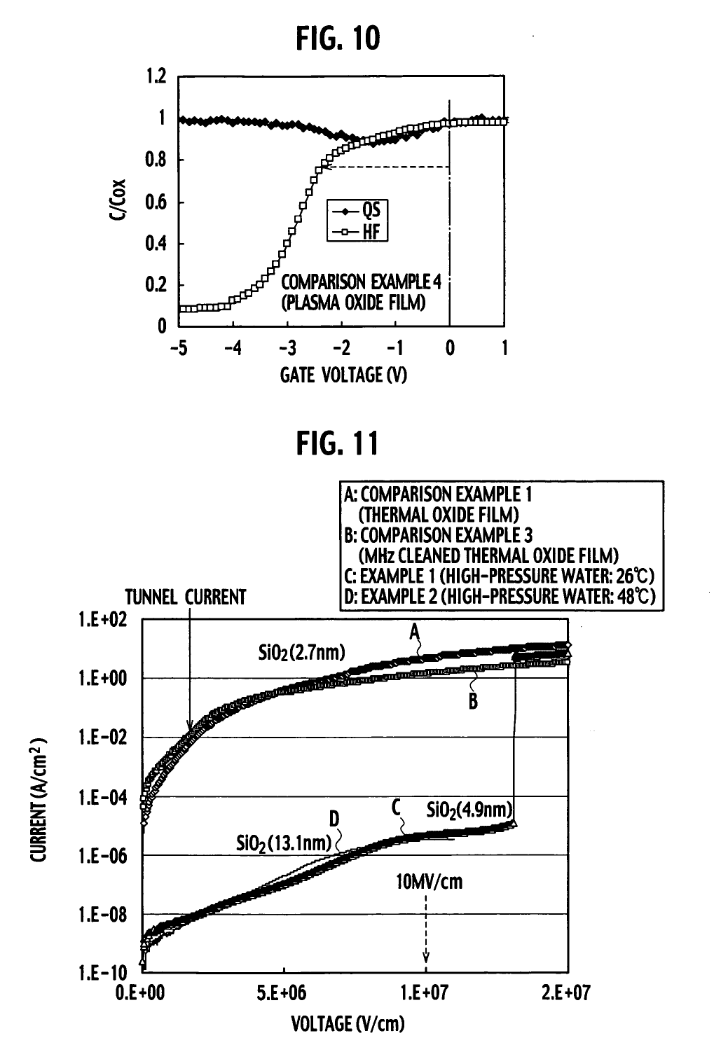

Refer to FIG. 10 as for QS value (Quasi Static-CV characteristic value), and HF-CV characteristics values of plasma oxide films formed at a substrate temperature of 400° C. Table 3 shows ΔV_{FB} and Dit value of the respective oxide films. As can be seen from Table 3, the plasma oxide film formed at 400° C. has ΔV_{FB} of −2.3 eV which is remarkably high, and Dit of 1.8×10¹³ eV⁻¹ cm⁻² which is somewhat high. When compared with the oxide film of Example 2 deposited by jetting high-pressure water, the plasma oxide film has its oxide film as well as its interface damaged, has a remarkably high fixed charge density.

TABLE 3

| | Thickness of thermal | | Dit(eV⁻¹ |
|---|---|---|---|
| | oxide film (nm) | Δ V_{FB}(V) | cm⁻²) |
| Oxide film made | 13.1 | −0.70 | 1.4E+13 |
| using 48° C. | | | |
| high-pressure water | | | |
| (Example 2) | | | |
| Thermal oxide film | 2.7 | −0.38 | 1.1E+11 |
| (Comparison | | | |
| Example 1) | | | |
| Oxide film by | 14.7 | −2.30 | 1.8E+13 |
| plasma oxidation | | | |
| (Comparison | | | |
| Example 4) | | | |

The oxide film of the Example 2 which is produced by jetting the high-pressure water is confirmed to be a good SiO₂ film whose V_{FB} is small and which has fewer damaged Si/SiO₂ interface than that of the oxide film made by the plasma oxidation. Further, the method of Example 2 is confirmed to substantially cause no thickness of the damaged layer.

Refer to FIG. 11 with respect to V-I characteristics representing withstand voltages and leak currents of MOS elements made using the oxide films of the Comparison Examples 1 and 3, and those of Examples 1 and 2 as gate oxide films. When producing the MOS elements, 400 nm thick and φ100 μm Al electrodes are deposited on the oxide films by the evaporation method.

The leak current of the MOS elements made on the gate oxide films which are formed by jetting the high-pressure water (of 26° C. and 48° C.) is 1×10⁻⁸ A/cm². This value is four figures larger than the leak current of the thermal oxide film, and two figures larger than the leak current of the TEOS film formed at 350° C. However, the foregoing value is confirmed to reliably meet the withstand voltage specification of 10 MV/cm of general CMOS (Complementary MOS) devices used as gate oxide films.

It is conceivable that the high withstand voltage is accomplished not only by the good quality of the oxide film and reduced damages but also by flat surfaces of the oxide films. This is because the high-pressure water jetted in the shape of a cluster seems effective in laterally sputtering the oxide films similarly to gas cluster beams.

According to the oxide film depositing method of the invention, water particles which do not contain any charged particles and are given kinetic energies by the high pressure promote oxidation of the substrate surfaces. Therefore, the method can reliably produce at low temperatures the oxide films which have good interface characteristics and are relatively free from damages.

### Further Embodiments

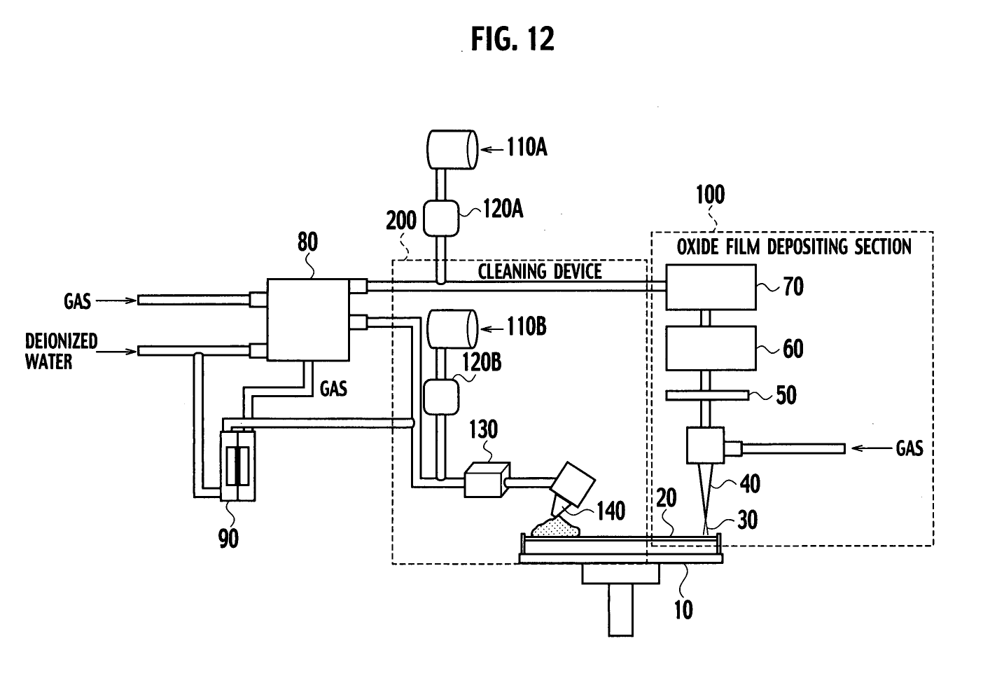

A modified example of the substrate treating unit (shown in FIG. 1) is shown in FIG. 12. The substrate heating unit includes a cleaning device 200, and can produce and clean oxide films.

The cleaning device 200 includes a nozzle 140 supplying a cleaning agent onto a silicon wafer 20. Deionized water is supplied from the feeder of the substrate treating unit, and the gas dissolving bath 80 of the substrate treating unit is also utilized. A chemical dispenser 110B is provided between the gas dissolving bath 80 and the nozzle 140, thereby supplying a proper amount of cleaning agent such as an etchant into an aqueous solution in which CO₂ gas is dissolved, via a liquid mass flow controller 120B.

If necessary, a submerged particle counter 130 may be provided in a supply tube. The substrate stand 10 of the substrate treating unit is also used for the cleaning. In other words, cleaning of the substrate and deposition of the oxide film can be conducted in one unit.

The high-pressure water jetted onto the substrate may be any aqueous solution such as alcohol so long as it contains the oxygen source. Alternatively, the chemical dispenser 110A may be provided and supply a chemical agent to the aqueous solution via the submerged mass flow controller 120A.

In an oxide film depositing unit 100, an N₂ gas pipe may be provided above the nozzle in order to jet the N₂ gas together with the high-pressure water, thereby controlling a jetting rate of the high-pressure water and a diameter of cluster particles.

According to the invention, the substrate treating unit can incorporate the cleaning device which cleans the substrate using the chemical agent, which is effective in improving productivity and reducing a manufacturing cost. Further, the substrate treating unit can use an existing cleaning device using chemical agents, which is effective in reducing investment cost, improving productivity, and reducing manufacturing cost.

Although the invention has been described with reference to particular embodiments, is it to be understood that those embodiments are merely illustrative of the application of the principles of the invention and should not be construed in limiting manner. Numerous other modifications may be made and other arrangements may be devised by those skilled in the art without departing from the spirit and scope of the present invention.

What is claimed is:

1. A method of manufacturing an oxide film, comprising jetting onto a substrate a high-pressure solution containing an oxygen source and having a pressure of 5 MPa, and forming an oxide film on the substrate using the jetted high-pressure solution.

2. The method of manufacturing the oxide film of claim 1, wherein the high-pressure solution contains water as a main component.

3. The method of manufacturing the oxide film of claim 1, wherein the high-pressure solution is substantially vertically jetted onto the substrate via a nozzle, and a pressure of the high-pressure solution on the substrate is substantially equal to a pressure applied to the high-pressure solution at the nozzle.

4. The method of manufacturing the oxide film of claim 2, wherein the high-pressure solution is substantially vertically jetted onto the substrate via a nozzle, and a pressure of the high-pressure solution on the substrate is substantially equal to a pressure applied to the high-pressure solution at the nozzle.

5. The method of manufacturing the oxide film of claim 1, wherein the high-pressure solution has a specific resistance of 0.1 MΩcm to 10 MΩcm or smaller at a room temperature.

6. The method of manufacturing the oxide film of claim 2, wherein the high-pressure solution has a specific resistance of 0.1 MΩcm to 10 MΩcm or smaller at a room temperature.

7. The method of manufacturing the oxide film of claim 3, wherein the high-pressure solution has a specific resistance of 0.1 MΩcm to 10 MΩcm or smaller at a room temperature.

8. The method of manufacturing the oxide film of claim 1, wherein the high-pressure solution contains a CO₂ gas.

9. The method of manufacturing the oxide film of claim 1, wherein the substrate is a silicon substrate.

10. The method of manufacturing the oxide film of claim 1, wherein the oxide film is 5 nm or more thick.

11. The method of manufacturing the oxide film of claim 1, wherein the high-pressure solution has a pressure of 10 MPa to 50 MPa.

12. The method of manufacturing the oxide film of claim 1, wherein the high-pressure solution has a pressure of 20 MPa to 30 MPa or lower.

13. A method of manufacturing an oxide film, comprising:
lowering a resistance of a solution serving as an oxygen source;
heating the solution to a room temperature or higher;
applying a pressure of 5 MPa or higher to the solution;
jetting the pressurized solution onto a substrate; and
depositing an oxide film on the substrate using the jetted high-pressure solution.

14. The method of manufacturing the oxide film of claim 13, wherein the solution is water which is itself an oxygen source, or contains oxygen, ozone or carbon dioxide dissolved as an oxygen source.

15. The method of manufacturing the oxide film of claim 14, wherein a soluble detergent or alcohol is dissolved in the solution.

16. The method of manufacturing the oxide film of claim 13, wherein the solution is deionized water; and the solution has a resistance reduced because of the CO₂ gas added therein.

17. A method of manufacturing a semiconductor device, comprising:
jetting onto a substrate a high-pressure solution which contains an oxygen source and has a pressure of 5 MPa or higher;
depositing an oxide film on the substrate using the high-pressure solution; and
forming an electrode on the oxide film, and forming an element having the oxide film and the electrode.

18. The method of manufacturing the semiconductor device of claim 17, wherein the element is either a capacitor or a transistor.

19. The method of manufacturing the semiconductor device of claim 17 further comprising: lowering the resistance of the high-pressure solution before it is jetted onto the substrate; and heating the solution to a room temperature or higher.

20. The method of manufacturing the semiconductor device of claim 17 further comprising jetting the high-pressure solution onto the substrate, forming an oxide film on the substrate, and cleaning the substrate.
